(19) United States
(12) Patent Application Publication
(10) Pub. No.: US 2006/0056214 A1
(43) Pub. Date: Mar. 16, 2006

(54) MEMORY MODULE WITH REDUCED INPUT CLOCK SKEW

(75) Inventors: Ryan M. Petersen, Sunnyvale, CA (US); Eric L. Nelson, Rancho Palos Verdes, CA (US)

Correspondence Address: HARTMAN & HARTMAN, P.C., 552 EAST 700 NORTH, VALPARAISO, IN, 46383, US

(73) Assignee: OCZ TECHNOLOGIES, INC., Sunnyvale, CA (US)

(21) Appl. No.: 11/161,977

(22) Filed: Aug. 24, 2005

Related U.S. Application Data
(60) Provisional application No. 60/522,169, filed on Aug. 25, 2004.

(51) Int. Cl. G11C 5/02

(52) U.S. Cl. 365/51; 365/189.05; 365/233

(57) ABSTRACT

A memory module capable of exhibiting reduced input clock skew. More particularly, an unbuffered memory module that comprises a substrate, multiple memory components mounted to the substrate, and input/output and address and command bus connectors that transmit digital information to and from the memory components further includes a phase lock loop (PLL) circuit that electrically interconnects a clock-in connector to the memory components for generating and transmitting a module clock signal to the memory components without routing any information to the memory components through a register. In this manner, the PLL operates to provide the memory module with an onboard clock generator that synchronizes the memory components of the module.

### CROSS REFERENCE TO RELATED APPLICATIONS

This application claims the benefit of U.S. Provisional Application No. 60/522,169, filed Aug. 25, 2004.

### BACKGROUND OF THE INVENTION

The present invention generally relates to digital circuits with components synchronized by a clock signal. More particularly, this invention relates to a memory module configured with an onboard phase lock loop circuit to reduce input clock skew among components of the module.

The computer industry has moved to higher speed grades not only in the field of processor technology but also relating to all peripheral devices including the system memory. The latter has become the main bottleneck in the overall system performance in that, with increasing clock rates, the central processors are starved for data and more and more cycles are wasted idly because of the lack of data and instructions to be processed.

Memory clock and data frequency are limited primarily by two different factors, the first being the core and input/output (I/O) design of the actual memory integrated circuit (IC) and the second being the interface with the rest of the system logic. With respect to the latter aspect, one critical factor is the dilution of the clock signals among the target devices. This dilution also leads to what is termed “clock skew,” characterized by components of a digital circuit receiving clock signals from a clock generator with slightly different time shifts as a result of the components not being equal distances from the generator. Within memory subsystems, this phenomenon is exacerbated by the ability to add and remove memory modules, which alters the capacitance and impedance of the system that directly contribute to clock skew. Currently employed strategies to address this problem include turning off clock signals to unused memory slots (sockets), both in order to reduce electromagnetic interference and to reduce the clock load that is wasted by the impedance of unused sockets without devices being used at any given time.

Despite all attempts to maximize the efficacy of the clock signals compared to the effective load on the clock and, consequently, reduce clock skew, overall memory frequencies attainable are still somehow inversely correlated to the total amount of memory or, by extension, the total number of devices that need to be driven. High density system memory configurations (such as those for servers) have worked around the load issue by using what is generally known as “registered” memory modules, which are typically dual in-line memory modules (DIMM's). As known in the art, a registered memory module is intended to reduce electrical loading on a memory bus by routing address and command lines through a register on the memory module. The register is interposed between the command and address bus to capture the commands and addresses, and then amplifies and distributes them on the next rising clock edge to the memory components. Registered memory modules also include a phase lock loop (PLL) circuit that locks on the frequency of the system clock input and generates its own stronger clock output that is sent to the individual devices. The main advantage of a registered memory module is that the chipset and system clock only see one component each, that is, the register and the PLL, respectively, and do not need to drive the entire clock, address, and command tree.

While the register amplifies the command and address signals, which are timed by the clock signal generated by the PLL, a notable disadvantage is the requirement for one additional latency cycle for the address and command translation after the chip select signal has been issued and before a row activate signal can be given. Because the register delays all information transferred to the module by one clock cycle, latencies are increased, primarily on random accesses. However, the same increase of latencies will be encountered on any access, even a page hit, in a non-streaming application where idle periods are inserted into the data transfers.

### BRIEF SUMMARY OF THE INVENTION

The present invention provides a method and device capable of reducing input clock skew on memory modules, with particular benefit to high-frequency memory modules, e.g., modules operating at 400 MHz data rate and beyond. More particularly, the present invention provides an unbuffered memory module comprising a substrate, multiple memory components mounted to the substrate, address and command connectors that transmit digital information to and from the memory components without routing the information through a register, and a phase lock loop (PLL) circuit on the substrate and electrically interconnecting a clock-in connector to the memory components for generating and transmitting a module clock signal to the memory components. In this manner, the phase lock loop circuit operates to provide the memory module with an onboard clock generator that synchronizes the memory components of the module.

In view of the above, the present invention has the ability to optimize the clock input to each memory component of the memory module, resulting in reduced clock skew-related errors, without the latency increases associated with the use of registered memory modules. Because the system clock signal sees only the PLL circuit, the load on the system clock is reduced, as are stray clock signals and noise. The invention provides the further possibility of optimizing a memory module, including its clock tree to the memory components, which is not susceptible to any possible trace variations in either width or length on the motherboard level that could introduce variations in signal propagation delays.

Other objects and advantages of this invention will be better appreciated from the following detailed description.

### BRIEF DESCRIPTION OF THE DRAWINGS

FIG. 1 schematically represents an unbuffered memory module equipped with a PLL in accordance with an embodiment of the present invention.

FIG. 2 schematically represents the PLL of FIG. 1 connected to the clock-in pin and one of the memory chips of FIG. 1.

### DETAILED DESCRIPTION OF THE INVENTION

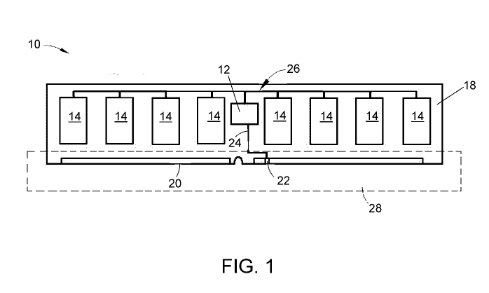

FIG. 1 depicts a memory module 10 having a conventional configuration for plugging into an available memory slot (socket) 28 (shown in phantom) of a computer memory subsystem (not shown), as is well known in the art. As such, the module 10 comprises a substrate 18 on which is mounted a number of memory components 14, such as DRAM, SDR SDRAM, or DDR SDRAM chips. In practice, the substrate 18 is typically in the form of a printed circuit board (PCB), though other types of substrates are also within the scope of this invention. To provide the electrical connection between the module 10 and the memory slot 28, the module 10 includes an edge connector 20 along the lower edge of the substrate 18, by which digital signals (command, address, and data) are transmitted to and from the components 14 through input/output (I/O) pins. As known in the art, the edge connector 20 can be configured such that the module 10 is a single in-line memory module (SIMM) or a dual in-line memory module (DIMM). According to the invention, the module 10 is unbuffered, meaning that addresses and commands are propagated to the memory components 14 without additional buffer delays.

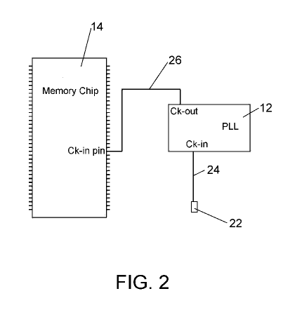

As represented in FIGS. 1 and 2, the current invention makes use of an onboard phase lock loop (PLL) circuit 12 (hereinafter, PLL 12) on the unbuffered memory module 10. The PLL 12 is electrically connected to a clock-in pin 22 of the edge connector 20 through a clock signal line 24, and also electrically connected to the memory components 14 through a clock tree 26 on the substrate 18. The PLL 12 receives the system clock signal from the computer through the clock-in pin 22 and, according to the known operation of PLL circuits, locks on the system clock signal and generates an amplified clock signal. According to the invention, the amplified (strengthened) and more precise clock signal is then transmitted directly to each of the memory components 14 through the clock tree 26. In this manner, the PLL 12 operates as an onboard clock generator that synchronizes (minimizes clock skew between) the memory components 14 of the module 10, enabling the components 14 to operate with the highest timing precision possible. While a variety of PLL circuit chips are commercially available and could be used by this invention, a particularly suitable PLL chip is the INCU877 1:10 zero-delay clock buffer chip manufactured by Inphi Corporation.

Because of the close proximity of the PLL 12 to each memory component 14 on the module 10 (as compared to the PLL associated with the system clock signal), and the absence of socketed interfaces that can cause signal reflections and other unwanted noise, the clock signal to each component 14 has a level of integrity (e.g., strength and precision) that is unattainable with conventional technology. A high clock signal integrity with minimized skew between any of the memory components 14 or, by extension, the I/O pins along the edge connector 20, results in a better “data-I” or “data valid” window. A longer “data valid” window with minimized skew across the bus, in turn, allows the ability to operate the same memory components 14 at higher frequencies with better reliability and lower error rates.

As is conventional for prior art memory modules, the module 10 is preferably manufactured such that all physical structures of the module 10, including the PLL 12, memory components 14, signal line 24, and clock tree 26, are not intended to be modified or replaced on the substrate 18. As such, the module 10 can be designed to optimize synchronization among the memory components 14 of the module clock signal generated by the PLL 12. Notable examples include the layout of the clock tree 26 and the quality of the memory components 14. Another advantage is that, because the PLL 12 generates the clock signal for the module 10, the removal of any memory module from another memory slot of the memory subsystem will not alter the clock signal received by the memory components 14 of the memory module 10.

As evident from FIG. 1, the module 10 lacks a register of the type required by prior art registered memory modules, which route command and address signal to memory components through a register. As such, the module 10 of this invention does not impose a delay in the initial access of memory data from the memory components 14 of the module 10 as occurs in registered modules.

In view of the above, the present invention fundamentally differs from previous uses of dedicated onboard PLL, in that the present invention is applicable to personal computers while previous uses of onboard PLL's have been exclusively limited to registered memory modules of servers and other high-density system memory configurations. The use of an unbuffered command and address bus in combination with the use of a dedicated PLL 12 per rank of memory components 14 in a memory subsystem allows the module designer to optimize the layout of the substrate 18 according to the exact specifications of the PLL 12 to warrant optimally synchronized clock input between all memory components 14 without incurring the access penalties associated with the use of registers. As such, the present invention allows the tightest control over the internal clocks of all memory components 14 and their optimal synchronization with the input/output clock supplied in the form of an I/O strobe. This is of particular importance in situations where multiple ranks of memory populate the memory subsystem of a motherboard, which results in a dilution of the clock signal and potentially in electromagnetic interference that introduces additional noise on the timing signals.

While the invention has been described in terms of a preferred embodiment, it is apparent that other forms could be adopted by one skilled in the art. For example, the physical configuration of an unbuffered memory module incorporating a PLL could differ from that shown. Therefore, the scope of the invention is to be limited only by the following claims.

What is claimed is:

1. An unbuffered memory module comprising a substrate, multiple memory components mounted to the substrate, address and command connectors and a clock-in connector on the substrate, the address and command connectors transmitting digital information to the memory components without routing the information through a register, and a phase lock loop circuit on the substrate and electrically interconnecting the clock-in connector to the memory components for generating and transmitting a module clock signal to the memory components, the phase lock loop circuit operating to provide the memory module with an onboard clock generator that synchronizes the memory components of the module.

2. The unbuffered memory module according to claim 1, wherein the phase lock loop circuit is electrically interconnected with the memory components through a clock tree configured to assist in synchronizing the module clock signal among the memory components.

3. The unbuffered memory module according to claim 1, further comprising a computer having a memory subsystem comprising a memory slot, wherein the unbuffered memory module is installed in the memory slot, the address and command connectors electrically connect the unbuffered memory module to the memory slot, and the clock-in connector delivers a system clock signal of the computer to the phase locked loop circuit.

4. The unbuffered memory module according to claim 3, wherein the computer is a personal computer and not a server.

5. The unbuffered memory module according to claim 3, wherein the memory slot is one of a plurality of memory slots of the memory subsystem, and removal of a memory module from one of the memory slots does not alter the module clock signal of the unbuffered memory module.

6. The unbuffered memory module according to claim 5, wherein each of the plurality of memory slots of the memory subsystem contains an unbuffered memory module according to claim 1.

7. The unbuffered memory module according to claim 6, wherein each of the unbuffered memory modules comprises a single phase lock loop circuit.

8. The unbuffered memory module according to claim 1, wherein the unbuffered memory module comprises a single phase lock loop circuit.

9. The unbuffered memory module according to claim 1, wherein the module is chosen from the group consisting of single in-line memory modules and dual in-line memory modules.

10. The unbuffered memory module according to claim 1, wherein the memory components are chosen from the group consisting of DRAM, SDR SDRAM, and DDR SDRAM chips.

11. The unbuffered memory module according to claim 1, wherein the module is a dual in-line memory module and the memory components are DDR SDRAM chips.

12. An unbuffered memory module installed in a memory slot of a memory subsystem of a personal computer, the unbuffered memory module comprising:
a substrate;
multiple memory components mounted to the substrate;
address and command connectors and a clock-in connector disposed along an edge of the substrate and electrically connected to the memory slot for transmitting digital information to and from the memory components without routing the information through a register, the clock-in connector receiving a system clock signal from the computer; and
a phase lock loop circuit on the substrate, electrically interconnected to the clock-in connector, and electrically connected to the memory components through a clock tree, the phase lock loop circuit generating and transmitting a module clock signal to the memory components at a higher precision than the system clock signal and synchronizing the memory components of the module.

13. The unbuffered memory module according to claim 12, wherein the clock tree is configured to assist in synchronizing the module clock signal among the memory components.

14. The unbuffered memory module according to claim 12, wherein the memory slot is one of a plurality of memory slots of the memory subsystem, and removal of a memory module from one of the memory slots does not alter the module clock signal of the unbuffered memory module.

15. The unbuffered memory module according to claim 14, wherein each of the plurality of memory slots of the memory subsystem contains an unbuffered memory module according to claim 12.

16. The unbuffered memory module according to claim 15, wherein each of the unbuffered memory modules comprises a single phase lock loop circuit.

17. The unbuffered memory module according to claim 12, wherein the module is chosen from the group consisting of single in-line memory modules and dual in-line memory modules.

18. The unbuffered memory module according to claim 12, wherein the memory components are chosen from the group consisting of DRAM, SDR SDRAM, and DDR SDRAM chips.
